(19) United States
(12) Patent Application Publication
(10) Pub. No.: US 2005/0092994 A1
(43) Pub. Date: May 5, 2005

(54) Display device

(75) Inventor: Nobuyuki Ishige, Shirako (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 10/962,439

(22) Filed: Oct. 13, 2004

(30) Foreign Application Priority Data
Oct. 29, 2003 (JP) 2003-368330

(51) Int. Cl. H01L 29/15

(52) U.S. Cl. 257/72

(57) ABSTRACT

The present invention provides a display device having a substrate which includes a display region on which a large number of pixels are arranged in a matrix array and drive circuits which drive the pixels outside the display region, wherein a drive circuit which applies signals to pixel circuits is directly built in the substrate outside the display region. A channel portion of a thin film transistor where a source electrode and a drain electrode face each other in an opposed manner which constitutes a drive circuit is formed in a bent shape which bends on a plane substantially parallel to the substrate.

### BACKGROUND OF THE INVENTION

1. Field of the Invention

The present invention relates to a flat panel type display device, and more particularly to a display device which realizes a rapid operation and the narrowing of a picture frame by directly building a gate drive circuit into a substrate which constitutes the display device together with a pixel circuit.

2. Description of Related Art

As a display device which is capable of performing a high-definition color display for a mobile phone, a notebook type computer, a display monitor or the like, a liquid crystal display device which uses a liquid crystal panel as a display panel, an organic electroluminescence display device (organic EL display device) which uses electroluminescence (particularly, organic electroluminescence) elements, a field emission type display device (FED) which uses field emission elements and the like have been already put into a practical use or have been studied aiming at the practical use.

This type of display device includes a substrate on which pixels which form an image display region and drive circuits are formed. For example, the liquid crystal display device which is popularly used as display means is configured such that, on a main surface of a first substrate which is preferably made of glass, a large number of pixels which include thin film transistor circuits are arranged in a matrix array, and the first substrate is laminated to a second substrate on which color filters which correspond to the respective pixels are formed, and liquid crystal is sealed in a gap defined between the laminated substrates.

Drive circuits are arranged outside the display region of the first substrate. The drive circuit includes a gate drive circuit which applies selection signals to gates of thin film transistors which constitute the pixels arranged in a matrix array on the display region, and a drain drive circuit which supplies display signals to drains of the thin film transistors selected by the gate drive circuit. As a drive method of the gate drive circuit, a gate selector method and a shift register method have been known.

Here, as a document which discloses this type of liquid crystal display device, Japanese Unexamined Patent Publication 2002-215118 is named.

### SUMMARY OF THE INVENTION

Recently, in a display device using amorphous silicon (a-Si) as a material of an activation layer of a thin film transistor of a pixel part, efforts have been made to obtain the enhancement of the resolution such as QVGA. Further, along with the enhancement of the high resolution, it has been proposed a method which directly incorporates a gate drive circuit in a substrate which constitutes the display region. A thin film transistor which constitutes the gate drive circuit is required to perform the rapid operation compared to the thin film transistors of the pixel part.

An operational speed of the thin film transistor is determined based on a width (a counter length between a source electrode and a drain electrode) of a semiconductor (here, a-Si: ASI) which is interposed between opposedly facing source electrode and drain electrode. A channel width of the thin film transistor which constitutes the gate drive circuit is required to be far greater than, that is, 10 to 20 times greater than a channel width of the thin film transistor which constitutes the pixel circuit.

However, when the channel width of the thin film transistor is widened, an area that the thin film transistors occupy on the substrate is increased and hence, an area of a peripheral portion which surrounds the display region is enlarged. This impedes the narrowing of a picture frame. When the channel width is narrowed to achieve the narrowing of the picture frame, this brings about the lack of an operational speed of the gate drive circuit and the lack of drive ability whereby the high-definition display cannot be realized.

In view of the above-mentioned circumstances, a display device of the present invention is characterized in that a channel width of thin film transistors which constitute a gate drive circuit is configured to be widened with in a limited area. That is, the present invention is directed to a display device comprising a substrate which includes pixels having first thin film transistor, a display region which arranges the plurality of pixel in a matrix array thereon, and drive circuit which drive the pixel outside the display region, wherein the drive circuit include a gate drive circuit which supplies selection signal to the first thin film transistor and a drain drive circuit which supplies display signal to the first thin film transistor selected by the gate drive circuit, wherein the gate drive circuit which applies the selection signal to the gates of the thin film transistor which constitute the pixel is directly built in the substrate outside the display region. The channel portion where the source electrode and the drain electrode of the second thin film transistor which constitutes the gate drive circuit face each other in an opposed manner is a bent shape which bends on a plane substantially parallel to the substrate.

Here, according to the present invention, semiconductor layers of the second thin film transistors which constitute the gate drive circuit can be formed along the bent shape of the channel portion or in a matted manner on a range which includes the channel portion. Then, by bending the opposedly facing portions of the source electrodes and drain electrodes, it is possible to form the bending of the channel portions. Further, it is possible to form the bending of the channel portion by forming a inter digital arrangement or a comb shape in which the source electrodes and the drain electrodes are engaged with each other.

Due to such a constitution, even when the channel width is equal, compared to the channels which extend in one direction, the bent channels can decrease an area which the thin film transistors occupy without deteriorating an operational function of the thin film transistor. As a result, it is possible to decrease a built-in area of the gate drive circuit which is arranged on the substrate and hence, the display region can be increased whereby the narrowing of the picture frame can be realized. Further, in case that the area in which the thin film transistors are built in the substrate is held equal, the channel width can be increased and hence, the shortage of operational speed or the shortage of the drive ability of the gate drive circuit can be overcome.

Here, the present invention is not limited to the above-mentioned constitution and the constitution of embodiments described later and various modifications can be made without departing from the technical concept of the present invention. Further, the application of the present invention is not limited to the liquid crystal display device and the present invention is applicable to various types of flat panel type display devices which adopt the active matrix driving including an organic electroluminescence (organic EL) display device, a field emission display device (FED), a plasma display device and the like.

### BRIEF DESCRIPTION OF THE DRAWINGS

FIG. 1 is a schematic plan view for explaining one example of a liquid crystal display device to which the present invention is applied;

FIG. 2 is a circuit diagram for explaining an essential part of one example of a gate drive circuit SR shown in FIG. 1;

FIG. 3 is a schematic plan view for explaining another example of a liquid crystal display device to which the present invention is applied;

FIG. 4 is a circuit diagram for explaining an essential part of one example of a gate selector GS shown in FIG. 3;

FIG. 5 is a schematic view of the representative constitution of a thin film transistor;

FIG. 6A and FIG. 6B are explanatory views of the structure of the thin film transistor for schematically explaining the embodiment 1 of the display device according to the present invention, wherein FIG. 6A is a plan view and FIG. 6B is a cross-sectional view;

FIG. 7A and FIG. 7B are explanatory views of the structure of the thin film transistor for schematically explaining the embodiment 2 of the display device according to the present invention, wherein FIG. 7A is a plan view and FIG. 7B is a cross-sectional view; and

FIG. 8A and FIG. 8B are explanatory views of the structure of the thin film transistor for schematically explaining the embodiment 3 of the display device according to the present invention, wherein FIG. 8A is a plan view and FIG. 8B is a cross-sectional view.

### DESCRIPTION OF THE PREFERRED EMBODIMENTS

The present invention is characterized in that, in a display device which includes a substrate comprising a display region which arranges a large number of pixels in a matrix array thereon and drive circuits which drive the pixels outside the display region, the drive circuit which supplies signals to the pixel electrode is directly built in the substrate outside the display region, and channel portions CH which opposedly face source electrodes SD1 and drain electrodes SD2 of the thin film transistors which constitute the drive circuit have a bent shape which bends on a plane substantially parallel to the substrate SUB1.

Hereinafter, embodiments of the display device of the present invention are explained in detail in conjunction with the drawings of the embodiment. Here, although the explanation is made with respect to the liquid crystal display device as an example in the embodiments described hereinafter, it is needless to say that the present invention is also applicable to the display device such as the organic EL display device, the FED or the like.

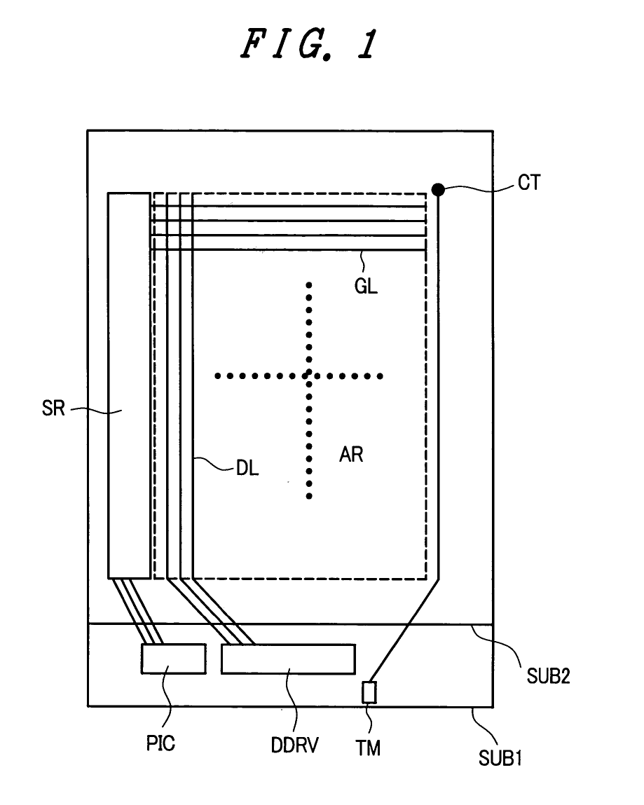

FIG. 1 is a schematic plan view for explaining one embodiment of the liquid crystal display device to which the present invention is applied. The liquid crystal display device is constituted by laminating a first substrate SUB1 which has a display region AR on which pixel circuits constituted of first type of thin film transistors and a second substrate SUB2 on which color filters are formed to each other and a liquid crystal layer is sealed in a lamination gap. The first substrate SUB1 has the thin film transistor circuits and hence, is also referred to as a thin film transistor substrate (TFT substrate), while the second substrate SUB2 is also referred to as the color filter substrate (CF substrate).

In the vicinity of the outside of the display region AR of the first substrate SUB1, a gate drive circuit which is directly built in using a so-called system-on-glass (SOG) method is arranged. The gate dive circuit is constituted of a shift register SR. On a portion of the first substrate SUB1 which projects from the second substrate SUB2, a drain drive circuit DDRV which constitutes a video drive IC and supplies display signals to drain electrodes of the thin film transistors of the pixel electrodes, and a PIC which constitutes a power source IC are mounted. Further, on the first substrate SUB1, terminals which are served for inputting various voltages and signal from an external signal source to the display device are formed. In FIG. 1, only the terminal TM which is served for applying a voltage of a common electrode formed on the second substrate SUB2 by way of a connection portion CT is shown.

The display region AR includes a large number of pixel circuits which are arranged in a matrix array and each pixel circuit is constituted of a thin film transistor circuit. In the inside of the display region AR, a large number of gate lines GL extend in one direction from the gate drive circuit SR formed outside the display region AR and are arranged in parallel, while a large number of drain lines DL extend in another direction which interests the above-mentioned one direction from the drain drive circuit DDRV and are arranged in parallel. Gate electrodes of the thin film transistors which constitute the pixel electrodes are connected with the above-mentioned gate lines GL, while display signals are supplied to the drain electrodes from the above-mentioned drain lines DL.

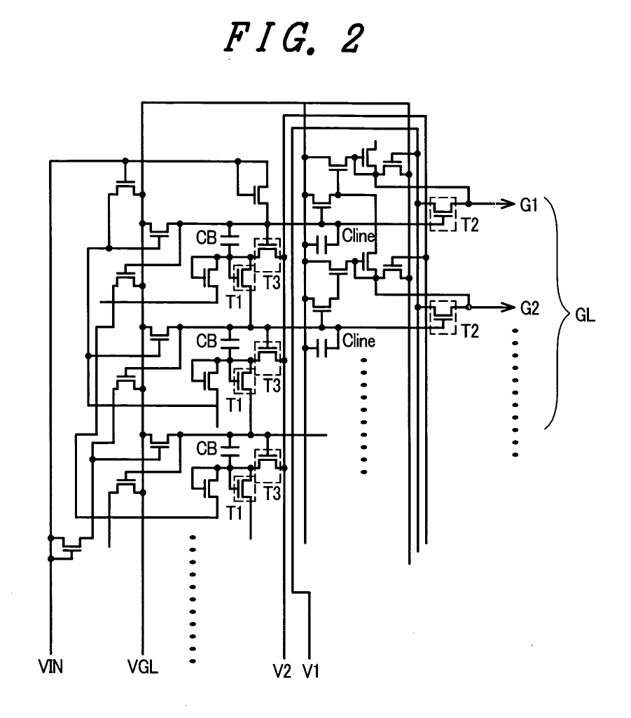

FIG. 2 is a circuit diagram for explaining an essential part of one example of the gate drive circuit SR shown in FIG. 1. The gate drive circuit SRis constituted of a shift register. The shift register is served for sequentially applying selection signals to the plurality of gate lines GL (G1, G2, G3, . . . GN), wherein an input pulse VIN is supplied to the gate drive circuit SR from the power source IC shown in FIG. 1. Further, a fixed power source or a ground potential VGL and synchronizing pulses V1, V2 are supplied to the gate drive circuit SR. In response to these input voltages, the gate G1 selection signal is outputted from a first-stage register which is constituted of second type thin film transistors T1, T2, a capacitance CB, a second type thin film transistor T2 and a capacitance Cline. The gate G2 selection signal is outputted from the next-stage register having the substantially equal constitution. Further, the gate G3 selection signals, . . . are outputted from the next-stage registers. Here, since the constitution and the manner of operation of the circuit are known, the detailed explanation thereof is omitted.

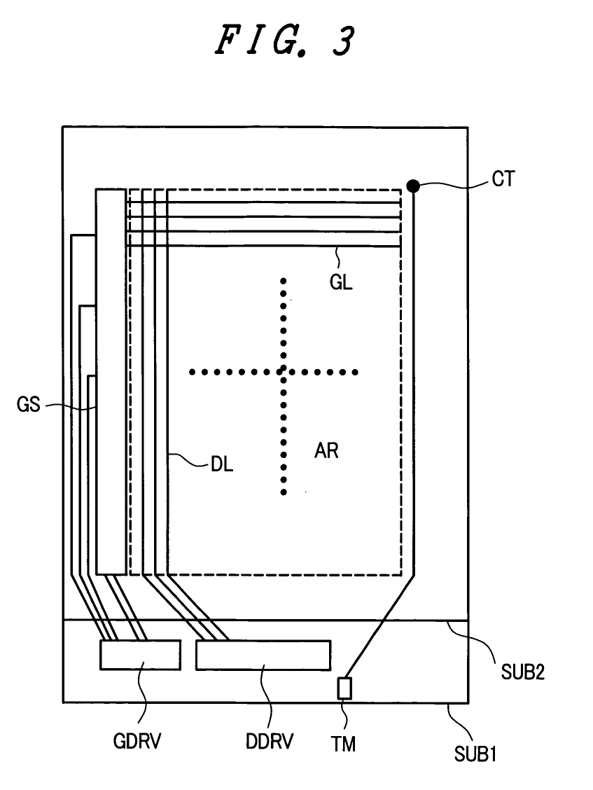

FIG. 3 is a schematic plan view for explaining another embodiment of the liquid crystal display device to which the present invention is applied. The liquid crystal display device is constituted by laminating a first substrate SUB1 which has a display region AR on which pixel circuits constituted of the first type of thin film transistors are arranged and a second substrate SUB2 on which color filters are formed to each other and a liquid crystal layer is sealed in a lamination gap.

In the vicinity of the outside of the display region AR of the first substrate SUB1, a gate selector GS is directly built in using a so-called system-on-glass (SOG) method. A scanning line drive circuit is constituted of scanning line drive IC GDRV which is mounted on a portion of the first substrate SUB1 which projects from the second substrate SUB2 and the gate selector GS. Further, on the portion of the first substrate SUB1 which projects from the second substrate SUB2, a drain drive circuit DDRV which constitutes a video drive IC for supplying display signals to drain electrodes of thin film transistors of the pixel circuits is mounted. Further, on the first substrate SUB1, terminals for inputting various voltages and signals to the display device from an external signal source are formed. In FIG. 3, only the terminal TM for applying a voltage of a common electrode provided to the second substrate SUB2 through a connection portion CT is shown.

The display region AR includes a large number of pixel circuits which are arranged in a matrix array and each pixel circuit is constituted of a thin film transistor circuit. In the inside of the display region AR, a large number of gate lines GL extend in one direction from the gate selector GS formed outside the display region AR and are arranged in parallel, while a large number of drain lines DL extend in another direction which interests the above-mentioned one direction from the drain drive circuit DDRV and are arranged in parallel. Gate electrodes of the second type thin film transistors which constitute the pixel electrodes are connected with the above-mentioned gate lines GL, while display signals are supplied to the drain electrodes from the above-mentioned drain lines DL.

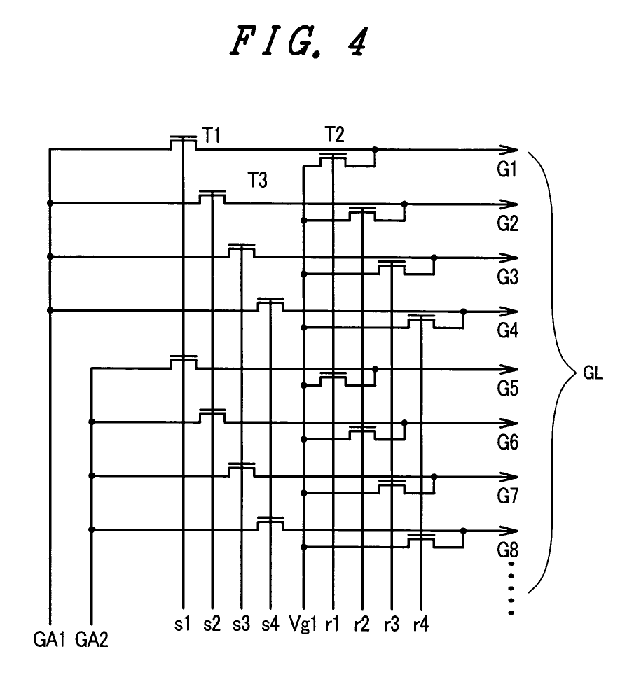

FIG. 4 is a circuit diagram for explaining an essential part of one example of the gate selector GS shown in FIG. 3. The gate selector GS is served for sequentially applying selection signals to the plurality of gate lines GL (G1, G2, G3, . . . , G8, . . . GN), wherein scanning signals GA1, GA2 are supplied to the gate selector GS from a scanning line drive IC GDRV shown in Fig. 3. Further, synchronizing pulses s1, s2, s3, s4, a fixed power source or a ground potential Vg1, synchronizing pulses r1, r2, r3, r4 are also supplied to the gate selector GS. In response to these input voltages, the gate G1 selection signal is outputted to a large number of gate lines from the thin film transistors T1, T3, T2. Here, since the constitution and the manner of operation of the circuit are known, the detail explanation thereof is omitted.

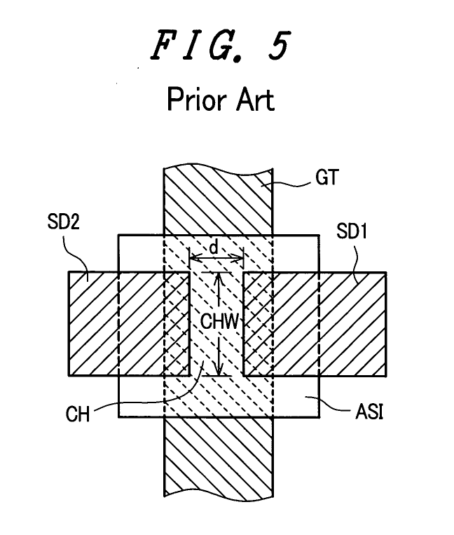

The present invention is also characterized by the constitution of the thin film transistors which constitute the gate line drive circuit of the display device shown in FIG. 1 to FIG. 4. FIG. 5 is a schematic view for explaining the representative constitution of the thin film transistor. The thin film transistor includes a gate electrode GT on (a main surface of) the substrate (preferably a glass substrate, not shown in the drawing) which constitutes the display device and a semiconductor layer ASI which constitutes an activation layer is formed on the gate electrode GT in an island shape. Then, on the semiconductor layer ASI, source/drain electrodes SD1, SD2 (for facilitating the explanation, indicated as a source electrode SD1 and a drain electrode SD2 in the drawing) are formed by patterning in a state that the electrodes SD1, SD2 face each other with a gap “d” therebetween.

The operational characteristics of the thin film transistor may depend on the mobility of the semiconductor layer ASI. However, provided that the mobility of the semiconductor layer ASI is common, the operational characteristics of the thin film transistor depend on a width CHW of the channel portion CH, wherein the source electrode SD1 and the drain electrode SD2 face each other in an opposed manner with the channel portion CH there between. That is, the greater (wider) the channel width CHW, the mobility between the source electrode and the drain electrode is increased so that the high-speed operation performance is enhanced.

[Embodiment 1]

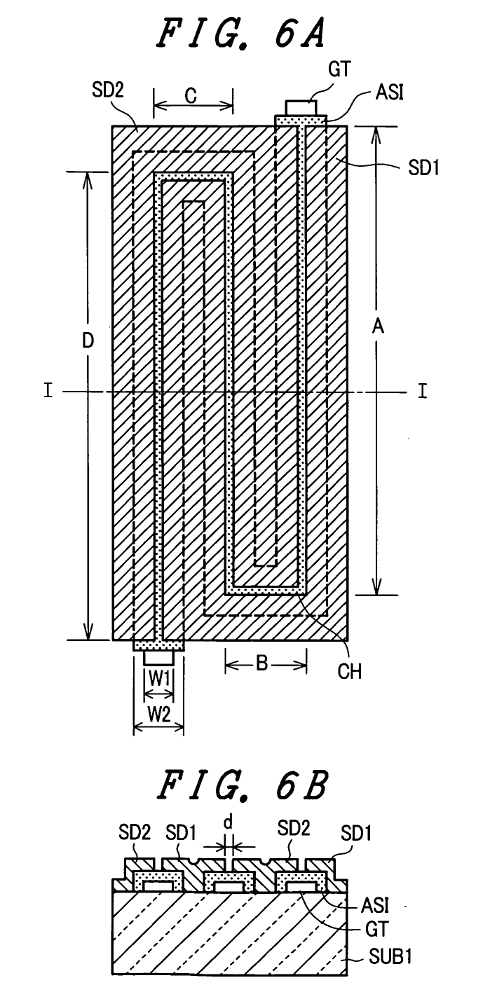

FIG. 6A is a plan view of a thin film transistor for schematically explaining the embodiment 1 of the display device according to the present invention and FIG. 6B is a cross-sectional view taken along a line I-I in FIG. 6A. In this embodiment, the thin film transistors which constitute the shift register circuit of the gate drive circuit explained in conjunction with FIG. 1 and FIG. 2 or the gate selector circuit of the gate drive circuit explained in conjunction with FIG. 3 and FIG. 4 have the structure shown in FIG. 6A and FIG. 6B.

In FIG. 6A and FIG. 6B, on the main surface of the glass substrate SUB1 which constitutes the first substrate, first of all, the gate electrode GT is formed by patterning in a state that the gate electrode GT is bent in a U shape with a lateral width w1. This bent pattern is a pattern formed by linking two U-shaped portions with each other. The gate electrode GT is the gate line GL per se, a partial extension of the gate line GL or a projection or a modification of the gate line. The semiconductor ASI is formed by patterning along the extending direction of the gate electrode GT so as to cover the gate electrode GT. The lateral width w2 of the semiconductor ASI is greater than the lateral width w1 of gate electrode GT and the semiconductor ASI is formed by patterning following the bending of the gate electrode GT. Over the semiconductor ASI, the source electrode SD1 is formed by pattering on one side along the extending direction of the gate electrode GT, while the drain electrode SD2 which faces the source electrode SD1 in an opposed manner with a given distance d therebetween is formed by pattering along the extending direction of the gate line. The bent pattern of this electrode is a so-called inter digital electrode which is a pattern in which the two U-shapes are engaged with each other.

In such a constitution, the width CHW of the channel CH with which the source drain SD1 and the drain electrode SD2 face each other in an opposed manner on the semiconductor ASI (or the extension width CHW of the channel CH) becomes A+B+C+D as shown in FIG. 6A. In this manner, according to this embodiment, by forming the channel CH in the bent manner in a U shape, it is possible to increase (or widen) the channel width CHW of the thin film transistor within a predetermined area on the substrate SUB1 and hence, the area that each transistor occupies can be decreased whereby the area in which the whole gate drive circuit is built on the substrate can be decreased thus realizing the high definition and the narrowing of the picture frame.

[Embodiment 2]

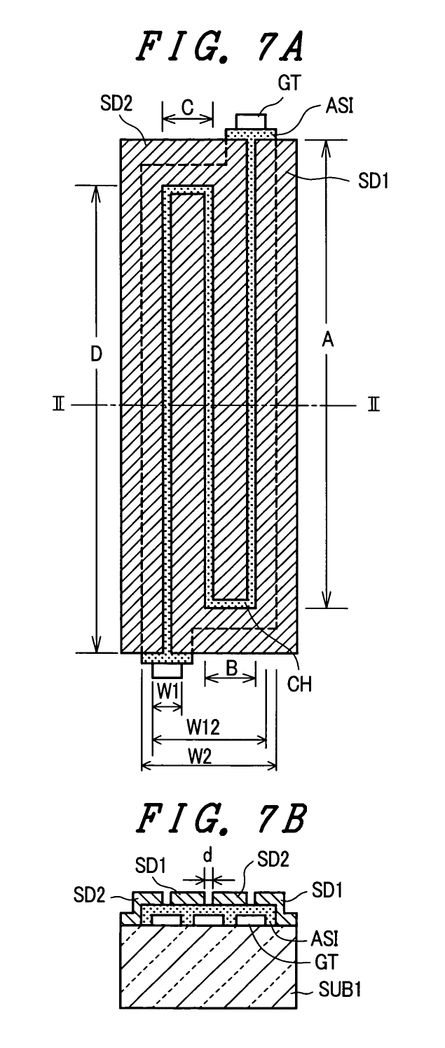

FIG. 7A is a plan view of a thin film transistor for schematically explaining the embodiment 2 of the display device according to the present invention and FIG. 7B is a cross-sectional view taken along a line II-II in FIG. 7A. In this embodiment, the thin film transistors which constitute the shift register circuit of the gate drive circuit explained in conjunction with FIG. 1 and FIG. 2 or the gate selector circuit of the gate drive circuit explained in conjunction with FIG. 3 and FIG. 4 has the structure shown in FIG. 7A and FIG. 7B.

In FIG. 7A and FIG. 7B, on the main surface of the first substrate SUB1, first of all, the gate electrode GT is formed by patterning in a state that the gate electrode GT is bent in an N shape with a lateral width w1. In the same manner as the embodiment 1, the gate electrode GT may be the gate line GL per se, a partial extension of the gate line GL or a projection or a modification of the gate line. The semiconductor ASI having a lateral width w2 is formed by patterning so as to cover the gate electrode GT. The semiconductor ASI is formed on the gate electrode GT by patterning such that the lateral width w2 of the semiconductor ASI is of a size which allows the semiconductor ASI to cover the gate electrode GT. The semiconductor ASI is formed such that the semiconductor ASI covers the folded-back gate electrode GT. That is, the lateral width w2 of the semiconductor ASI is greater than a width w12 of the folded-back gate electrode GT. Then, the source electrode SD1 is formed by pattering on one side along the extending direction of the gate electrode GT, while the drain electrode SD2 which faces the source electrode SD1 in an opposed manner with a given distance d therebetween is formed by pattering along the extending direction of the gate line GL.

In such a constitution, the width CHW of the channel CH with which the source electrode SD1 and the drain electrode SD2 face each other in an opposed manner on the semiconductor ASI (or the extension width CHW of the channel CH) becomes A+B+C+D as shown in FIG. 7A. In this manner, also according to this embodiment, by forming the channel CH in the bent manner in an N shape, it is possible to increase (or widen) the channel width CHW of the thin film transistor within a predetermined area on the substrate SUB1 and hence, the area that each transistor occupies can be decreased whereby the area in which the whole gate drive circuit is built on the substrate can be decreased thus realizing the high definition and the narrowing of the picture frame.

[Embodiment 3]

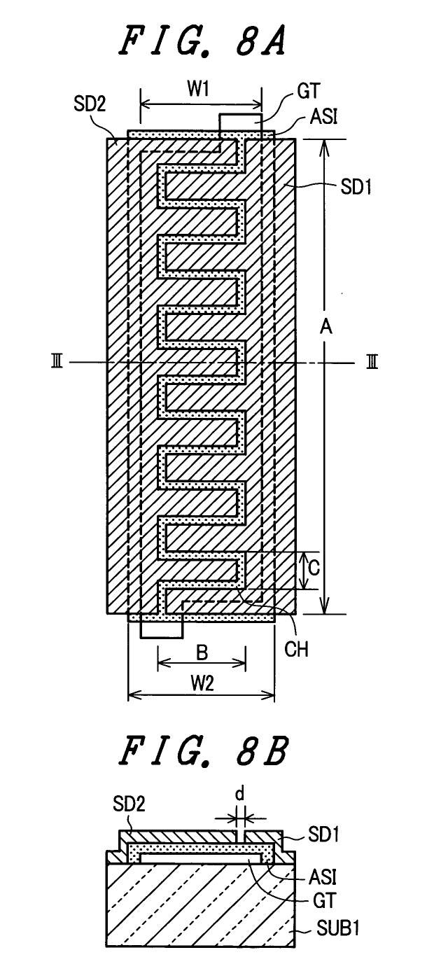

FIG. 8A is a plan view of a thin film transistor for schematically explaining the embodiment 3 of the display device according to the present invention and FIG. 8B is a cross-sectional view taken along a line III-III in FIG. 8A. In this embodiment, the thin film transistors which constitute the shift register circuit of the gate drive circuit explained in conjunction with FIG. 1 and FIG. 2 or the gate selector circuit of the gate drive circuit explained in conjunction with FIG. 3 and FIG. 4 have the structure shown in FIG. 8A and FIG. 8B.

In FIG. 8A and FIG. 8B, on the main surface of the first substrate SUB1, first of all, the gate electrode GT is formed in a matted manner or uniformly by patterning with a lateral width w1. In the same manner as the embodiments 1 and 2, the gate electrode GT may be the gate line GL per se, a partial extension of the gate line GL or a projection or a modification of the gate line. The semiconductor ASI having a lateral width w2 is formed by patterning so as to cover the gate electrode GT. The semiconductor ASI is formed on the gate electrode GT by patterning such that the lateral width w2 of the semiconductor ASI is of a size which allows the semiconductor ASI to cover the gate electrode GT. On the semiconductor ASI, the gate electrode GTSD1 and the drain electrode SD2 which are formed in a comb shape (or a inter digital shape) are engaged with each other thus forming a channel CH between opposedly-facing portions thereof. The drain electrode SD2 is formed by patterning in a state that the drain electrode SD2 faces the source electrode SD2 with a given gap “d” in the extending direction of the gate line GL. The source electrode SD1 and the drain electrode GT face each other in an opposed manner in the direction perpendicular to the longitudinal direction of the gate electrode GT.

In such a constitution, the width CHW of the channel CH with which the source electrode SD1 and the drain electrode SD2 face each other in an opposed manner on the semiconductor ASI (or the extension width CHW of the channel CH) becomes A+nB+mC as shown in FIG. 8A. n and m are determined depending on the number of comb shapes. Since n=13 and m=14 in FIG. 8A, the channel width CHW of this embodiment becomes A+13B+14C. In this manner, also in this embodiment, by forming the channel CH in a state that the channel CH is bent in a comb shape, it is also possible to increase (or widen) the channel width CHW of the thin film transistor within a predetermined area on the substrate SUB1 and hence, the area that each transistor occupies can be decreased whereby the area in which the whole gate drive circuit is built on the substrate can be decreased thus realizing the high definition and the narrowing of the picture frame.

The present invention is not limited to the liquid crystal display device and is also applicable to the display device of an active matrix type such as the organic EL display device and the FED display device. Further, the present invention is also applicable to other general semiconductor device.

1. A display device comprising a substrate which includes pixel having first thin film transistor, a display region which arranges a plurality of the pixel in a matrix array thereon, and drive circuit which drive the pixel outside the display region,
wherein the drive circuit includes a gate drive circuit which supplies selection signal to the first thin film transistor and a drain drive circuit which supplies display signal to the first thin film transistor selected by the gate drive circuit,
the gate drive circuit includes second thin film transistor which is directly built in the substrate and the second thin film transistor includes a source electrode and a drain electrode which are arranged to face each other in an opposed manner with a semiconductor film formed on the substrate interposed therebetween,
channel portion where the source electrode and the drain electrode face each other in an opposed manner is bent on a plane substantially parallel to the substrate.

2. A display device according to claim 1, wherein the semiconductor layer which constitutes the channel portion is formed in a bent shape of the channel portion.

3. A display device according to claim 1, wherein the semiconductor layer which constitutes the channel portion is formed in a matted manner in a range which covers the channel portion.

4. A display device according to claim 1, wherein the source electrode and the drain electrode are formed of an electrode having an inter digital shape.

5. A display device according to claim 4, wherein the semiconductor layer is formed along opposedly facing portions of the source electrode and the drain electrode.
